(19) United States
(12) Patent Application Publication
(10) Pub. No.: US 2007/0201547 A1
(43) Pub. Date: Aug. 30, 2007

(54) Decision feedback equalizer adaptation

(75) Inventors: Benjamin Alec Willcocks, Bristol (GB); Philip Mark Daniell, Gloucestershire (GB)

Correspondence Address: NIXON & VANDERHYE, PC, 901 NORTH GLEBE ROAD, 11TH FLOOR, ARLINGTON, VA, 22203, US

(73) Assignee: Phyworks Limited, Bristol (GB)

(21) Appl. No.: 11/395,542

(22) Filed: Apr. 3, 2006

(30) Foreign Application Priority Data
Feb. 28, 2006 (GB) 0603993.7

(51) Int. Cl. H03H 7/30

(52) U.S. Cl. 375/233

(57) ABSTRACT

A decision feedback equalizer includes at least one quantizer, able to quantize a received signal according to a comparison with a one of multiple quantization thresholds. Each quantization threshold corresponds to one or more than one value of one or more than one previously received symbols. The equalizer further includes level selection circuitry, for setting the quantization thresholds based on statistical measurements taken in connection with signals having the corresponding value of one or more previously received signal. For each category of received signal having the corresponding value of one or more previously received signal, the circuitry determines at least one upper threshold, representing a first specific percentile in the upper half of the distribution of received signals in said category; determines at least one lower threshold, representing a second specific percentile in the lower half of the distribution of received signals in said category; and determines the quantization threshold based on the upper and lower thresholds.

This invention relates to a receiver, and in particular to a receiver which includes an equalizer to compensate for distortion introduced by a communications channel.

### BACKGROUND OF THE INVENTION

In a conventional binary data transmission system, a sequence of data bits is transmitted over a communications medium. A receiver then attempts to recreate the transmitted sequence. That is, for each received bit, the receiver determines whether the transmitted bit is more likely to have been a “1” or a “0”. In doing so, the receiver must deal with the fact that the received signal will not be a perfect copy of the transmitted bit sequence, but will show the effects of changes to the waveform introduced by the communications medium, and will include an additional noise component.

For many communications media, one source of changes to the waveform is inter-symbol interference (ISI). That is, energy from one bit period is received in another bit period. In the case of optical fibres, ISI results from the fact that components of optical signals travel along an optical fibre at different speeds.

The presence of ISI greatly increases the probability that the receiver will fail to determine correctly whether a specific transmitted bit was a “1” or a “0”. That is, it greatly increases the probability of bit errors.

It is known, however, that it is possible to compensate for ISI. A particular transmitted waveform results in a particular received waveform, and the relationship between the transmitted waveform and the received waveform can be expressed mathematically as a transfer function. An equalizer can be provided in the receiver, which applies a second transfer function to the received waveform. If the second transfer function can be made to approximate the inverse of the first transfer function, then the effects of ISI can be approximately compensated. This approach is known as equalization. One type of equalization is decision feedback equalization.

FIG. 1 is a block schematic diagram illustrating a decision feedback equalizer 10 for binary-valued symbols, having two feedback taps.

The equalizer 10 receives an input signal on an input line 12. The input signal may for example have been received along an optical fibre, and then converted into an electrical signal, with the magnitude of the electrical signal corresponding to the 5 magnitude of the received light signal, and then subject to linear filtering. The input signal is applied to a summing element 14, which adds to the input signal two compensation values, which, as will be described below, approximately compensate for the ISI effects of the two immediately previously received symbols.

The output of the summing element 14 is applied to a comparator 16, which quantizes the summing element output as either “+1” or “−1” by comparing it with a reference “0” value, and outputs the result to a first delay element 18, having a first feedback tap 20 on its output, and then to a second delay element 22, after which a second feedback tap 24 is positioned. The quantized +1 or −1 value is then provided as an output of the equalizer.

The effect of ISI is that the value of the transmitted signal during one signal period affects the value of the received signal not only during the corresponding signal period, but also during other signal periods. This illustrated equalizer attempts to compensate for the effect of the value of the transmitted signal during the two signal periods following the corresponding signal period.

Thus, it is determined in advance that a transmitted +1 value has the effect of increasing the value of the received signal by an amount Vp1 in the immediately following signal period, and has the effect of increasing the value of the received signal by an amount Vp2 in the next signal period after that. Conversely, a transmitted −1 value has the effect of decreasing the value of the received signal by the amount Vp1 in the immediately following signal period, and has the effect of decreasing the value of the received signal by the amount Vp2 in the next signal period after that.

It is these effects that the equalizer seeks to compensate. Thus, based on the value of the signal at the first feedback tap 20, an appropriate compensating value (+Vp1 or −Vp1), depending on whether the signal value is −1 or +1, respectively, is selected, and fed back to the summing element 14. Similarly, based on the value of the signal at the second feedback tap 24, an appropriate compensating value (+Vp2 or −Vp2), depending on whether the signal value is −1 or +1, respectively, is selected, and fed back to the summing element 14.

Thus the ISI effects of the two previous symbols in a transmitted bit sequence can be compensated for in a received symbol.

FIG. 2 shows an improvement on the decision feedback equalizer shown in FIG. 1. Elements of the equalizer 30 that correspond to the equalizer 10 of FIG. 1 are indicated by the same reference numerals. In this case, however, the equalizer 10 comprises level selection circuitry 26.

In this implementation, each of the feedback taps 20, 24 outputs its respective quantized result to the level selection circuitry 26. The level selection circuitry 26 provides an output having one of four possible feedback values. Each of these four feedback values corresponds to one of the four possible combinations of the values of the two previous received signals, i.e. +1, +1; +1, −1; −1, +1; and −1, −1. The level selection circuitry 26 selects the appropriate value to feed back to the summing element 14, based on the inputs from the two feedback taps 20, 24. For example, the level selection circuitry 26 may comprise a look-up table, in which the four possible feedback values are stored.

The document “An Adaptive RAM-DFE for Storage Channels”, Fisher, et al, IEEE Transactions on Communications, vol. 39, no. 11, November 1991, pages 1559-1568, discloses a decision feedback equalizer of this type, in which the values stored in the look-up table can be adaptively updated, in order to take account of variations in the effect of ISI, by examining errors in the compensated input signal.

A aper by Keshab K Parhi (“Pipelining in Algorithms with Quantizer Loops”, IEEE Transactions on Circuits and Systems, vol. 38, no. 7, July 1991, pages 745-754) describes a method whereby the decision feedback loop can be avoided by replicating the quantization hardware to simultaneously make all of the possible quantization decisions and then using logic circuitry to identify, on a symbol-by-symbol basis, which of the quantization results to use.

### SUMMARY OF INVENTION

According to the present invention, there is provided a decision feedback equalizer, comprising one or more quantizers, the or each quantizer being adapted to quantize a received signal according to a comparison with a respective one of a plurality of quantization thresholds, each quantization threshold corresponding to one or more than one value of one or more than one previously received symbols. The equalizer further includes circuitry, the circuitry being adapted to calculate the quantization thresholds based on statistical measurements taken in connection with signals having the corresponding value of one or more previously received signal. For each category of received signal having the corresponding value of one or more previously received signal, the circuitry is adapted to determine at least one upper threshold, representing a first specific percentile in the upper half of the distribution of received signals in said category; determine at least one lower threshold, representing a second specific percentile in the lower half of the distribution of received signals in said category; and determine the quantization threshold based on the upper and lower thresholds.

Thus, each quantization threshold may correspond to one value of the previously received symbol or symbols, or the number of quantization thresholds may be reduced by allowing one or more of the quantization thresholds to correspond to more than one value of the previously received symbol or symbols.

Further, each quantization threshold may correspond to a value of one previously received symbol, where the equalizer compensates for ISI over one bit period, or may correspond to a combination of values of more than one previously received symbol, where the equalizer compensates for ISI over a corresponding number of bit periods.

In a preferred embodiment, the upper and lower thresholds have an average of 50, i.e. the upper threshold has the same percentage of samples above it as the lower threshold has below it, and the quantization threshold is the midpoint of the upper and lower thresholds.

In another preferred embodiment, the number of quantizers is larger than the number of possible combinations of previously received symbols, and larger than the number of quantization thresholds that are set. Each of the quantizers is used in turn to calculate the statistics to update the quantization threshold. This embodiment has the advantage of allowing continuous operation of the equalizer whilst simultaneously updating the quantization thresholds.

Thus the present invention provides an improved decision feedback equalizer.

### BRIEF DESCRIPTION OF THE DRAWINGS

For a better understanding of the present invention, and to show more clearly how it may be carried into effect, reference will now be made, by way of example, to the following drawings, in which:

FIG. 1 is a block schematic diagram illustrating a decision feedback equalizer for binary-valued symbols, having two feedback taps.

FIG. 2 is a block schematic diagram illustrating an improved decision feedback equalizer.

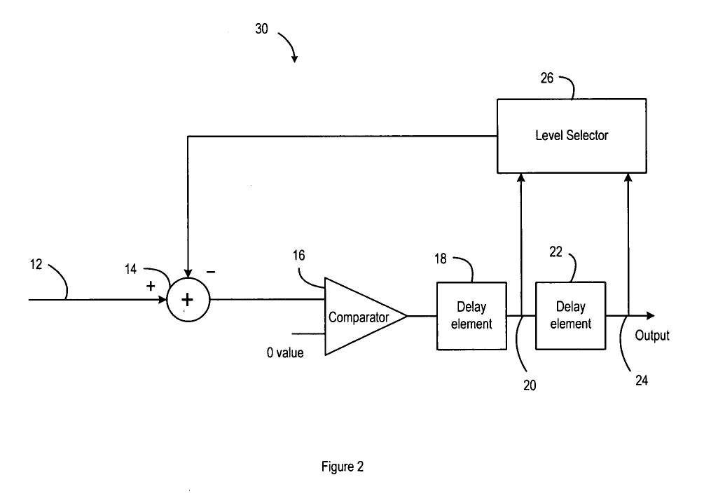

FIG. 3 is a block schematic diagram illustrating a decision feedback equalizer for binary-valued symbols and having two feedback taps, according to the present invention.

FIG. 4 is a schematic diagram illustrating received signal distributions according to the combination of previously received symbols.

FIG. 5 is a block schematic diagram illustrating a decision feedback equalizer according to an aspect of the present invention.

FIG. 6 is a block schematic diagram illustrating a decision feedback equalizer according to another aspect of the present invention.

### DETAILED DESCRIPTION OF THE PREFERRED EMBODIMENTS

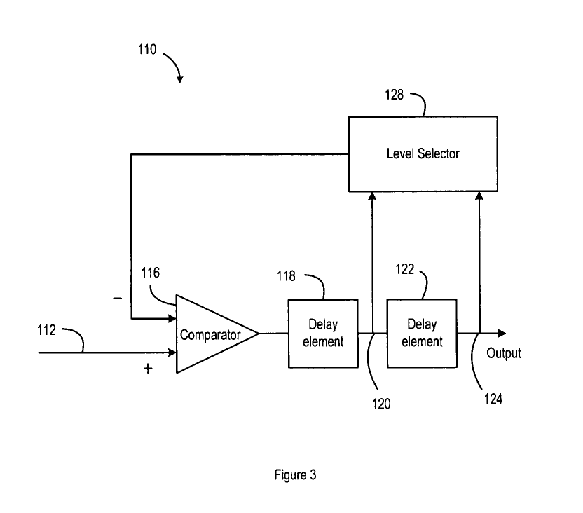

FIG. 3 illustrates a decision feedback equalizer 110 according to the present invention.

In this embodiment, rather than generating a compensating value to feed back and add to the received signal, the previously received symbols are used to generate a quantization threshold value to feed back to the comparator. The input signal is then compared with an appropriate quantization threshold value according to the combination of previously received symbols.

Thus, the equalizer 110 receives an input signal on an input line 112. The input signal may for example have been received along an optical fibre, and then converted into an electrical signal, with the magnitude of the electrical signal corresponding to the magnitude of the received light signal. The input signal is applied to a first input 114 of a comparator 116.

A quantization threshold value is applied to the second input 118 of the comparator 116, and the quantization threshold value as will be described below, approximately compensates for the ISI effects of the two immediately previously received symbols.

The comparator 116 quantizes the input signal as either +1 or −1 by comparing it with the quantization threshold value, and outputs the result to a first delay element 118, having a first feedback tap 120 on its output, and then to a second delay element 122, after which a second feedback tap 124 is positioned. The quantized +1 or −1 value is then provided as an output of the equalizer.

In this illustrated embodiment of the invention, each of the feedback taps 120, 124 outputs its respective quantized result to the level selection circuitry 128. The level selection circuitry 128 provides an output having one of four possible feedback values. Each of these four feedback values corresponds to one of the four possible combinations of the values of the two previous received signals, i.e. +1, +1; +1, −1; −1, +1; and −1, −1. For example, the level selection circuitry 128 may comprise a look-up table, in which four possible quantization threshold values are stored. The level selection circuitry 128 selects the appropriate quantization threshold value to feed back to the second input 118 of the comparator 116, based on the inputs from the two feedback taps 120,124.

As mentioned previously, the received signal is also input to the comparator 116, and is compared during each signal period with the quantization threshold value input from the level selection circuitry 128.

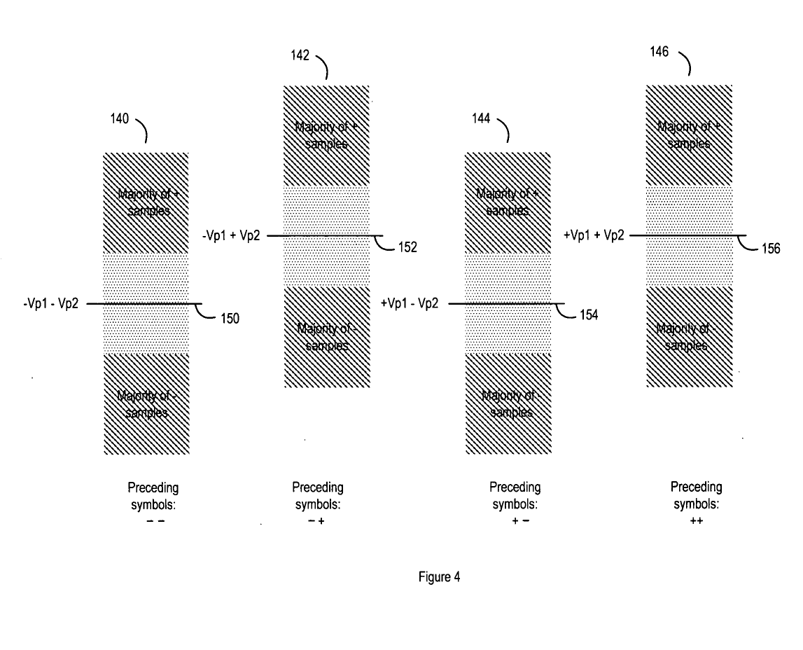

FIG. 4 is a schematic diagram illustrating possible distributions 140, 142, 144, 146 of received signals according to the combination of previously received symbols.

The first distribution 140 corresponds to the signals where the previously received symbols were −1, −1; the second distribution 142 corresponds to the signals where the previously received symbols were −1, +1; the third distribution 144 corresponds to the signals where the previously received symbols were +1, −1; and the fourth distribution 146 corresponds to the signals where the previously received symbols were +1, +1.

As can be seen from FIG. 4, each of the distributions 140, 142, 144, 146 is somewhat similar, with a bulk of symbols at some positive value, representing a +1 symbol; another bulk of symbols at some relative negative value, representing a −1 symbol; and fewer symbols in between the two aforementioned bulks of symbols.

In addition, each of the distributions 140, 142, 144, 146 is offset from the others by a certain amount. This effect results from the ISI from previously received symbols.

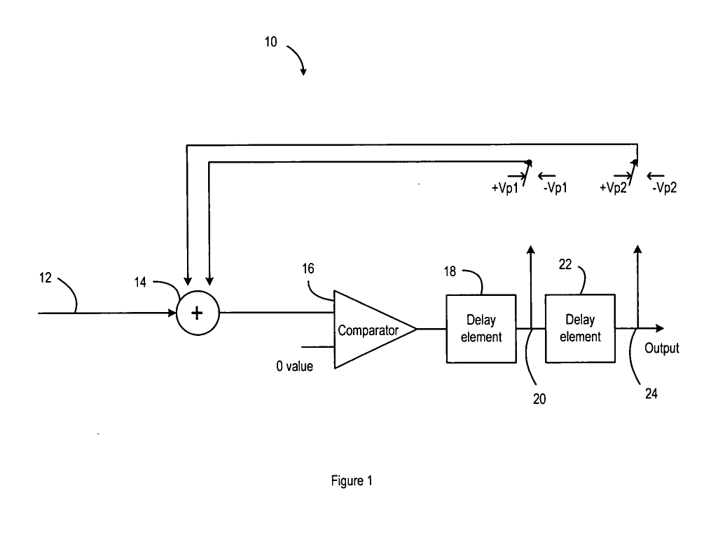

This effect is counteracted by introducing a separate quantization threshold for each distribution. As shown in FIG. 4, a first quantization threshold 150 is used for the first distribution 140; a second quantization threshold 152 is used for the second distribution 142; a third quantization threshold 154 is used for the third distribution 144; and a fourth quantization threshold 156 is used for the fourth distribution 146. For ease of illustration, and comparison with FIG. 1, these four quantization thresholds 150,152, 154, 156 are indicated as being the sums of a first component ±Vp1, representing ISI from the immediately preceding signal period, and a second component ±Vp2, representing ISI from the next preceding signal period. However, it will be appreciated that in practice there may not in fact be any such relationship amongst the four quantization thresholds 150, 152, 154, 156.

It may appear that an ideal implementation would be to calculate the respective quantization thresholds such that 50% of the relevant signals are above the threshold, and 50% are below the threshold. However, in practice this does not give the best results because of the sparsity of samples at the desired quantization level and because the transmitted bit sequence may not include an exactly equal proportion of +1 and −1 symbols.

In the present invention, secondary upper and lower thresholds are calculated such that a first certain percentage of signals fall above the upper threshold, and a second certain percentage of signals fall below the lower threshold. The quantization threshold can then be calculated from the upper and lower thresholds.

In one preferred embodiment, the first certain percentage is equal to the second certain percentage, and the quantization threshold is the mid-point between the upper and lower thresholds.

In another preferred embodiment, the method of setting a quantization threshold disclosed in GB-A-2401291 is used to set each of the four quantization thresholds 150, 152, 154, 156. That is, considering each group of samples in turn, a first secondary upper threshold A₁ and a first secondary lower threshold A₀ are calculated such that a first percentage, a, of signals fall above the upper threshold, and the first percentage, a, of signals fall below the lower threshold. Then, a second secondary upper threshold B₁ and a second secondary lower threshold B₀ are calculated such that a second percentage, b, of signals fall above the upper threshold, and the second percentage, b, of signals fall below the lower threshold. The first and second percentages a and b may be in the range of 25%-45%. The quantization threshold VS can then be calculated from these thresholds, by solving the equation:

$$\frac{\vert {V}_{s} - {A}_{1} \vert}{\vert {A}_{1} - {B}_{1} \vert} = \frac{\vert {V}_{s} - {A}_{0} \vert}{\vert {A}_{0} - {B}_{0} \vert}$$

However, the person skilled in the art may think of many other different ways of using upper and lower thresholds to calculate the quantization threshold, and it is to be understood that these are all within the scope of the present invention

These methods have several advantages:

First, the percentages of received symbols falling above and below the upper and lower thresholds respectively can be calculated such that there is a high degree of certainty in their positions. For example, the thresholds could be chosen such that 45% of received symbols within a group fall above the upper threshold and 45% fall below the lower threshold, leaving 10% of received symbols in between the upper and lower thresholds. In this case, the density of received symbols at the 45^{th} and 55^{th} percentiles is large enough that the positions of the quantization thresholds are not changed significantly due to noise in the received signal or a small imbalance in the proportions of transmitted +1 and −1 symbols.

Second, the upper and lower thresholds are very easy to calculate.

Third, the invention does not depend on the actual magnitude of the received signal, as the only requirement is to find relative thresholds based on percentages of received symbols.

The invention has been described so far with reference to a binary valued signal, in which a single quantization decision is required, in order to determine whether the received signal is considered to be a +1 or a −1. However, it will be appreciated that the system can be adapted for use with non-binary-valued symbols, in which case there will necessarily be a greater number of upper and lower thresholds, such that (n-1) pairs of upper and lower thresholds are required for n-level symbols. This can be seen by considering that one pair of upper and lower thresholds is necessary for each gap between symbol values.

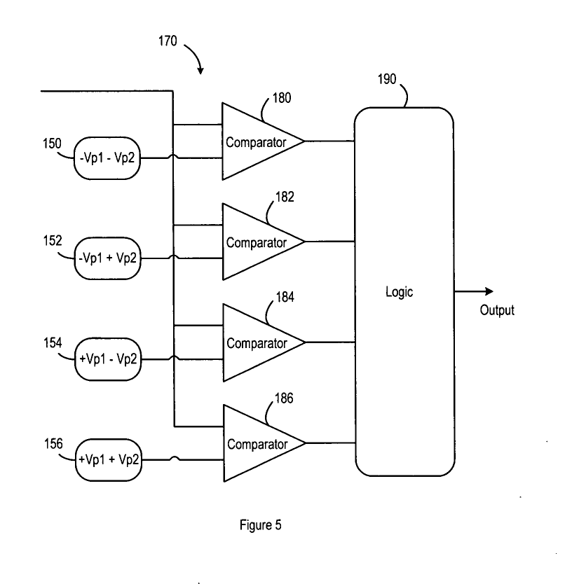

FIG. 5 is a schematic block diagram of an alternative implementation of the present invention.

In this equalizer 170, a plurality of comparators are used in parallel to facilitate higher speed decision-feedback implementation. Thus, a received signal is passed simultaneously to each of the comparators 180, 182, 184, 186. In this example, the equalizer 170 has four comparators each corresponding to one possible combination of previously received symbols for use in the case of a two-feedback-tap equalizer for binary-valued symbols. A first comparator 180 compares the received signal to the quantization threshold 150 (−1, −1); a second comparator 182 compares the received signal to the quantization threshold 152 (−1, +1); a third comparator 184 compares the received signal to the quantization threshold 154 (+1, −1); and a fourth comparator 186 compares the received signal to the quantization threshold 156 (+1, +1).

Each comparator makes a separate quantization decision based on its respective quantization threshold, and outputs the result to logic circuitry 190. The logic circuitry 190 selects which of the four comparison results output to use, based on the particular combination of previously received symbols, and outputs the appropriate result. The logic circuitry 190 is further responsible for updating the quantization thresholds 150, 152, 154, 156 according to one of the aforementioned methods.

This implementation greatly speeds up the decision feedback process, because it removes the comparators from the feedback loop. All possible decisions are made in parallel, and only after this has happened is the appropriate result chosen.

Of course, it should be appreciated that the equalizer described in FIG. 5 is for exemplary purposes only, and differences may readily be thought of by one skilled in the art that fall within the scope of the present invention. For example, it is not necessary to have one comparator per category of previously received symbols. Fewer comparators could be required if one or more of the comparators performs quantizations for more than one combination of previously received symbols.

That is, as described above, four categories of input signals were considered, giving rise to four distributions, namely where the previously received symbols were −1, −1; where the previously received symbols were −1, +1; where the previously received symbols were +1, −1; and where the previously received symbols were +1, +1. Four quantization thresholds were obtained, and applied to four quantizers. However, if two or more of the quantization thresholds are sufficiently similar, then a single quantizer, operating with a single quantization threshold, can be used to quantize two or more of the categories of input signal.

In the case of the equalizers 110, 170, shown in FIGS. 3 and 5, the setting of the secondary thresholds, in order to adapt the quantization thresholds, can be performed using the comparators of the equalizer while the equalizer is off-line, and not generating output signals.

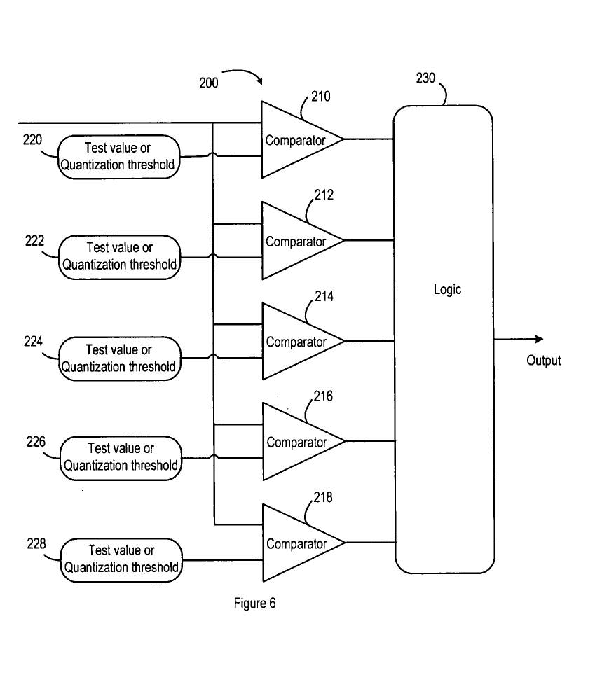

FIG. 6 is a block schematic diagram illustrating a further implementation of the present invention, which is able to adapt the quantization thresholds while in use without introducing errors. Again, the example in FIG. 6 is directed towards a decision feedback equalizer with two feedback taps and adapted for use with binary symbols.

In this example, the equalizer 200 comprises five comparators 210, 212, 214, 216, 218, and the received signal is input to all five comparators. Five quantization thresholds 220, 222, 224, 226, 228 are input to the five comparators 210, 212, 214, 216, 218, respectively.

The operation is similar to that for the equalizer 170 in FIG. 5. Thus, four of the five comparators compare the received signal with a respective one of the quantization thresholds, and output the result to logic circuitry 230. The logic circuitry 230 then selects the appropriate input according to the combination of previously received symbols and outputs the corresponding result.

However, the introduction of an extra comparator allows the equalizer 200 to perform continuous decision feedback equalizer operation, whilst simultaneously updating the quantization thresholds.

To this end, while four of the comparators are quantizing received signals, the extra comparator is collecting statistics for one possible combination of previously received symbols, with a view to updating the respective quantization threshold. After a certain number of received signals have been processed, and therefore a reasonable set of statistics obtained, the respective quantization threshold is updated as required, and then the comparator collecting statistics takes over the quantizing role for that combination of previously received symbols.

The comparator which had previously been performing quantizations for that combination then starts collecting statistics for another combination of previously received symbols, and so on.

Of course, it will be appreciated that, for this example, up to four extra comparators could be used in this way to update the quantization thresholds more rapidly, whilst still maintaining continuous decision feedback equalizer operation.

This aspect of the present invention has additional benefits not heretofore mentioned. In addition to inter-symbol interference, received signals are also subject to offsets present in the system itself. Thus, one comparator may introduce an offset when compared to another comparator. However, using the same comparator to collect statistics and update the quantization threshold as to perform the quantization based on that quantization threshold, as described above, negates this extra source of error.

It should be understood that, although throughout this document we refer to a decision feedback equalizer for binary-valued symbols and having two feedback taps, the present invention is equally applicable to equalizers for non-binary-valued symbols with any number of feedback taps.

Thus, for more advanced systems with more than two feedback taps, there will be a greater number of possible combinations of previously received symbols. Similarly, there will be a greater number of possible combinations of previously received symbols if non-binary-valued symbols are used. However, the basic principles of the invention remain the same in both cases.

1. A decision feedback equalizer, comprising:
one or more quantizers, the or each quantizer being capable of quantizing a received signal according to a comparison with a respective one of a plurality of quantization thresholds, each quantization threshold corresponding to one or more than one value of one or more than one previously received symbols;
wherein the equalizer comprises level selection circuitry, the level selection circuitry being adapted to set the quantization thresholds based on statistical measurements taken in connection with signals having the corresponding value of one or more previously received signal;
wherein, for each category of received signal having the corresponding value of one or more previously received signal, the circuitry is adapted to:
determine at least one upper threshold, representing a first specific percentile in the upper half of the distribution of received signals in said category;
determine at least one lower threshold, representing a second specific percentile in the lower half of the distribution of received signals in said category; and
determine the quantization threshold based on the upper and lower thresholds.

2. A decision feedback equalizer as claimed in claim 1, wherein the first specific percentile and the second specific percentile have an average of 50, and the quantization threshold is midway between the upper and lower thresholds.

3. A decision feedback equalizer as claimed in claim 1, wherein, for each category of received signal having the corresponding value of one or more previously received signal, the circuitry is adapted to:
determine a first secondary upper threshold A₁ and a first secondary lower threshold A₀ such that a first percentage of signals fall above the upper threshold, and the first percentage of signals fall below the lower threshold;
determine a second secondary upper threshold B₁ and a second secondary lower threshold B₀ such that a second percentage of signals fall above the upper threshold, and the second percentage of signals fall below the lower threshold; and
determine the quantization threshold from the first secondary upper threshold, the first secondary lower threshold, the second secondary upper threshold; and the second secondary lower threshold.

4. A decision feedback equalizer as claimed in claim 3, wherein the circuitry is adapted to determine the quantization threshold Vₛ from the equation:
$$\frac{\vert {V}_{s} - {A}_{1} \vert}{\vert {A}_{1} - {B}_{1} \vert} = \frac{\vert {V}_{s} - {A}_{0} \vert}{\vert {A}_{0} - {B}_{0} \vert} .$$

5. A decision feedback equalizer as claimed in claim 1, comprising one quantizer, wherein the circuitry is adapted to select a quantization threshold from said plurality of quantization thresholds, for use by said quantizer, based on the value of one or more previously received signal.

6. A decision feedback equalizer as claimed in claim 1, comprising a plurality of quantizers, each quantizer being adapted to quantize a received signal according to a comparison with a respective quantization threshold, wherein the circuitry is adapted to select an output from said plurality of quantizers, based on the value of one or more previously received signal.

7. A decision feedback equalizer as claimed in claim 6, wherein the number of quantizers is smaller than the number of categories of received signal.

8. A decision feedback equalizer as claimed in claim 6, wherein the number of quantizers is larger than the number of categories of received signal, and wherein each of the quantizers is used in turn to make said statistical measurements for one of said categories of received signal, and then to act as the quantizer for that category of received signal.

9. A decision feedback equalizer as claimed in claim 1, for use with binary-valued received signals.

10. A decision feedback equalizer as claimed in claim 1, for use with received signals having more than two possible values.

11. A decision feedback equalizer as claimed in claim 1, wherein each quantization threshold corresponds to a combination of values of a plurality of previously received signals.

12. A decision feedback equalizer, comprising:
a plurality of quantizers, each quantizer being adapted to quantize a received signal according to a comparison with a respective threshold; and
circuitry, the circuitry being adapted to calculate a plurality of quantization thresholds based on statistical measurements taken in connection with categories of received signals having corresponding values of one or more previously received signal;
wherein the circuitry is adapted to:
apply said quantization thresholds to said quantizers such that each received signal is compared with said quantization thresholds, and then for each received signal to select an output from one of said quantizers based on the value of one or more previously received signal; and
apply a test value to at least one of said quantizers such that said statistical measurements can be taken.

13. A decision feedback equalizer as claimed in claim 12, wherein the circuitry is adapted to apply sequencing such that at any point in time all necessary quantizer functions are performed and continuous decision feedback equalization operation achieved, while at the same time said statistical measurements are being taken.

14. A decision feedback equalizer as claimed in claim 12, wherein a respective test value is applied to each of said quantizers in turn and, when a quantizer has been used to take statistical measurements in connection with a category of received signal, it is then used to quantize received signals in that category.
